(19) United States
(12) Patent Application Publication
(10) Pub. No.: US 2021/0195752 A1
(43) Pub. Date: Jun. 24, 2021

(54) SECONDARY DEVELOPMENT AND REVISION METHOD OF MOTHERBOARD BASED ON HEAT MANAGEMENT

(71) Applicant: Huan-Tang Lin, Taoyuan (CN)

(72) Inventor: Huan-Tang Lin, Taoyuan (CN)

(21) Appl. No.: 16/882,722

(22) Filed: May 25, 2020

(30) Foreign Application Priority Data
Dec. 18, 2019 (CN) 201911307530.X

(51) Int. Cl. H05K 3/00

(52) U.S. Cl. CPC H05K 3/0005

(57) ABSTRACT

A secondary development and revision method for the motherboard based on heat management, wherein the secondary development and revision is carried out according to the public PCB issued by the motherboard chip supplier, euthermic chips are classified according to the size of heat and operating temperature range of the euthermic chips to match the power of the heat dissipation device used; at the same time, taking into account the size specifications and position of connector, in the condition of forming a smooth air flow channel as far as possible, the euthermic chips are arranged on both sides of the motherboard. The disclosure realizes the scattered arrangement of the heating components on the motherboard, improves the heat accumulation condition inside the product in essence, makes the cooling channel more direct, and improves the heat dissipation cost, power consumption, conduction medium and reliability of the product.

### TECHNICAL FIELD OF THE DISCLOSURE

The disclosure relates to the field of circuit board manufacturing, in particular to a secondary development and revision method of motherboard based on heat management.

### BACKGROUND OF THE DISCLOSURE

The design of conventional computing products takes the motherboard as a fixed module, product design can only be adapted to the motherboard. However, the motherboard is the main body of the product, and directly affects and determines the structure of the product.

Therefore, all computer motherboards carry out the same design specifications, the compatibility developing to a certain stage results in homogenization of products, at the same time, with the significant improvement of computing performance, the use of heat dissipation technology methods has been greatly limited, the product heat problem is prominent, and power consumption used for heat dissipation greatly increased. In addition, obvious features of the original motherboard design are a single-sided arrangement, easy to cause heat accumulation inside the product, and increasing of the cooling link.

### SUMMARY OF THE DISCLOSURE

The disclosure provides a secondary development and revision method for the motherboard based on heat management to solve at least one of the above technical problems.

In order to solve the above problems, as an aspect of the present disclosure, it is provided a secondary development and revision method for the motherboard based on heat management, wherein the secondary development and revision is carried out according to the public PCB issued by the motherboard chip supplier, euthermic chips are classified according to the size of heat and operating temperature range of the euthermic chips to match the power of the heat dissipation device used; at the same time, taking into account the size specifications and position of connector, in the condition of forming a smooth air flow channel as far as possible, the euthermic chips are arranged on both sides of the motherboard.

Further, during the development and revision, keep the chipset in the original side while modify the pin definition of the connector; and/or, keep the connector in the original side while realize the reversal mirror of the chip.

Further, a high heating surface is arranged on the outside of the product to make a cooling device and an external structure connected together, and to make the cooling channel directly connected to the outside.

Further, the motherboard adopts a power saving passive cooling.

The disclosure breaks the original design thinking trend of the motherboard, realizes the scattered arrangement of the heating components on the motherboard, improves the heat accumulation condition inside the product in essence, makes the cooling channel more direct, and significantly improves the heat dissipation cost, power consumption, conduction medium and reliability of the product. For example, to use the laminated multi-board technology for the layout of the mainboard, the CPU, GPU, memory, SSD, South Bridge, North Bridge could be arranged respectively in different directions and in the correct position (e.g. front and back) with respective layout in different layers to achieve the purpose of disclosure.

### BRIEF DESCRIPTION OF THE DRAWINGS

FIG. 1 is the structural schematic of the present disclosure.

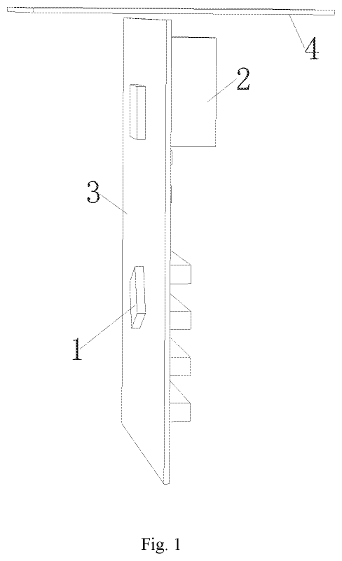

Reference Numerals: 1, euthermic chip; 2, connector; 3, motherboard; 4, external structure.

### DETAILED DESCRIPTION OF THE EMBODIMENTS

The embodiments of the disclosure will be described below in detail in conjunction with the accompanying drawings, but the disclosure may be implemented in many different ways defined and covered by Claims.

In the process of various types of computer product design, the present disclosure does not take the motherboard as a shaped component, but to classify the heat components (CPU, chipset, rectifier tube, on-board graphics card, etc.) and non-heating components (connector, IO interface, etc.) of the motherboard and adopt three-dimensional arrangement on double side to separate and disperse the heat sources to make full use of the mutual cooperation between cooling device and cooling space, in order to optimize the product overall design for larger implementation space of the heat dissipation management.

After determining the specifications of the motherboard, the secondary development and revision is carried out according to the public PCB issued by the motherboard chip supplier. Euthermic chips 1 are classified according to the size of its heat and operating temperature range to match the power of the heat dissipation device used. At the same time, taking into account the size specifications and position of connector 2, in the condition of forming a smooth air flow channel as far as possible, the euthermic chips arrange on both sides of the motherboard 3. Different from the conventional application of line design software in a single and flatten mode, a double-side design needs a three-dimensional consideration. In a specific implementation process, two technical solutions are usually used. One is to keep the chipset in the original side, while modify the pin definition of the connector. The other is to keep the connector in the original side, while realize the reversal mirror of the chip.

The above-mentioned changes in the layout of the motherboard cause changes in the internal structure and appearance of the product, and directly change the homogenization of the product and improve the market competitiveness of the product.

Because the chips attached to the PCB is relatively consistent in height of shape and the difference with the connectors thereof is large, classifying the high heat dissipation chip with the layout on the other side can improve the applicable processing conditions of heat dissipation devices, reduce the complexity, and fully avoid the heat dissipation barrier formed by components, such as cards attached to the original motherboard, and cables. Classifying the chip with low heat can reduce the heat in ambient space, and greatly reduce the balance point of exchange with the external air, after the high heat source is separated.

The motherboard designed by the disclosure removes the constraints and qualifications from the traditional motherboard. Therefore, the application of various heat dissipation management measures to reduce the cooling energy consumption and improve heat dissipation efficiency becomes more flexible. This motherboard can be arranged in different orientations inside the product, for example, the up, middle, and down, or the left, middle, and right. For example, to arrange the high heating surface on the outside of the product (up, down, left, right, back, and forth) can make the cooling device and the external structure 4 connected together, make the cooling channel directly to the outside, and the original heat from the chip to the inside of the product, and then to the outside of the product by the power fan is changed. To be arranged in the middle of the product, a smoother air flow channel can be designed to facilitate the planning of the air path.

In the new structure above, due to the separation of heat and better use of the external structure 4 and the environment, heat dissipation efficiency and cost power consumption are optimized under the conditions the same total heat generation of the product. For example, the original which needs a strong discharging active heat dissipation turns into a power saving passive cooling, it not only solves the heat accumulation but also eliminate the fan noise and the negative heat dissipation results brought by dust, and truly achieve the implementation effect of low-carbon green environmental protection. In addition, it also changed the situation of fixing the heat dissipation device to the fragile motherboard 3, thus improving the reliability of the product.

In short, after the adoption of the present disclosure, compared with conventional computer heat management methods, there are different degrees of optimization and improvement in the three major evaluation elements of complexity, flexibility, implementation effect.

The disclosure breaks the original design thinking trend of the motherboard, realizes the scattered arrangement of the heating components on the motherboard, improves the heat accumulation condition inside the product in essence, makes the cooling channel more direct, and significantly improves the heat dissipation cost, power consumption, conduction medium and reliability of the product. For example, to use the laminated multi-board technology for the layout of the mainboard, the CPU, GPU, memory, SSD, South Bridge, North Bridge could be arranged respectively in different directions and in the correct position (e.g. front and back) with respective layout in different layers to achieve the purpose of disclosure.

The above are only the preferred embodiment of the disclosure and are not intended to limit the disclosure, for those skilled in the art, various changes and variations may be made to the disclosure. Any revisions, equivalent replacements, improvements and the like within the spirit and principle of the disclosure shall be contained within the scope of protection of the claims of the disclosure.

What is claimed is:

1. A secondary development and revision method of motherboard based on heat management, wherein the secondary development and revision is carried out according to the public PCB issued by the motherboard chip supplier, euthermic chips (1) are classified according to the size of heat and operating temperature range of the euthermic chips (1) to match the power of the heat dissipation device used; at the same time, taking into account the size specifications and position of connector (2), in the condition of forming a smooth air flow channel as far as possible, the euthermic chips (1) are arranged on both sides of the motherboard (3).

2. The secondary development and revision method of motherboard based on heat management according to claim 1, wherein, during the development and revision, keep the chipset in the original side while modify the pin definition of the connector; and/or, keep the connector in the original side while realize the reversal mirror of the chip.

3. The secondary development and revision method of motherboard based on heat management according to claim 1, wherein a high heating surface is arranged on the outside of the product to make a cooling device and an external structure (4) connected together, and to make the cooling channel directly connected to the outside.

4. The secondary development and revision method of motherboard based on heat management according to claim 1, wherein the motherboard (3) adopts a power saving passive cooling.
